(19) United States
(12) Patent Application Publication
(10) Pub. No.: US 2015/0365063 A1
(43) Pub. Date: Dec. 17, 2015

(54) LUMPED ELEMENT FREQUENCY SELECTIVE LIMITERS

(71) Applicant: Metamagnetics Inc., Canton, MA (US)

(72) Inventors: Anton L. Geiler, Chestnut Hill, MA (US); John D. Adam, Millersville, MD (US)

(21) Appl. No.: 14/737,851

(22) Filed: Jun. 12, 2015

Related U.S. Application Data
(60) Provisional application No. 62/011,841, filed on Jun. 13, 2014.

(51) Int. Cl. H03H 7/24

(52) U.S. Cl. CPC H03H 7/24

(57) ABSTRACT

A lumped element frequency selective limiter device and corresponding method for the design is provided, including a variety of LE-FSL device structures and systems. The devices can utilize ferrite-based materials in a lumped element inductor operable at and above 1 GHz. The methods and systems can utilize devices having cascaded configurations of lumped elements to improve operating performance the devices.

### RELATED APPLICATION

This application claims priority to, and the benefit of, co-pending U.S. Provisional Application No. 62/011,841, filed Jun. 13, 2014, which is expressly and entirely incorporated herein by reference.

### FIELD OF THE INVENTION

The present invention relates to the field of frequency selective limiter (FSL) devices used for differential signal attenuation in applications such as multi-function phased array antennas, e.g., to mitigate interference problems, and, more generally, mobile wireless communications. In particular, the present invention relates to a lumped element frequency selected limiter (LE-FSL) device suitable for differential signal attenuation in at least the microwave range using ferrite-based materials. The present invention relates, in addition, to cascaded LE-FSL device structures.

### BACKGROUND

Generally, signal interference, whether self-induced or external, whether intended or unintended, is a severe problem in many communications, radar and other defense electronics systems. FSLs hold potential for increasing performance of broadband microwave receivers in the presence of large interfering signals. In contrast to conventional semiconductor limiters that attenuate all signals within the pass-band when one of the signals exceeds the threshold power level, Frequency Selective Limiters (FSL) are ferrite devices that automatically attenuate large, above-threshold power level signals, while allowing below-threshold signals within the pass-band to pass with little attenuation. In other words, the FSL is a passive device that can automatically track the frequency of a high power signal and reduce, with frequency selectivity, the amplitude of that high power signal to a threshold power level.

Early ferrite FSLs used ceramic ferrites in waveguide configurations as power limiters to provide protection to the input of a radar receiver from the transmitted radar pulse reflection or leakage. Interest in broadband limiters with lower threshold power levels and useful frequency selectivity spurred the development of FSLs using single crystal YIG spheres coupled to dielectric or strip-line resonators. Recently, broadband FSLs with threshold power levels appropriate for receiver applications have been attained using distributed strip-line YIG (yttrium iron garnet) single crystal-based FSL structures. The distributed strip-line YIG single crystal-based FSL structures utilized a narrow center conductor which gave approximately 50 Ω characteristic impedance when a 100 μm thick YIG film was used as the strip-line dielectric, resulting in a greater than octave bandwidth without matching. The narrow strip-line conductor also produced high RF magnetic fields resulting in threshold power level of 0 dBm, suitable for interference mitigation applications. The strip-line FSL was 38 mm×5 mm×2 mm plus bias magnets, had a limiting range of 19 dB and a small signal insertion loss ≦3 dB over the 2.5 to 5.3 GHz range. Fabrication and design details of the strip-line FSL are given in U.S. Pat. No. 4,845,439.

However, YIG single crystal-based strip-line FSLs have a number of shortcomings. As one example, although YIG films of thickness ≧100 μm can be attained, quality films are increasingly difficult to attain as film thickness increases. Film thickness affects the attainable volume of the ferrite-based FSL material, the power absorbed by the dielectric ferrite-based FSL material, and the limiting dynamic range of the FSL device. High performance strip-line FSLs are thus, for example, not as readily compatible with the size and packaging configurations of present and future mobile wireless devices and phased array electronics.

### SUMMARY

There is a need for reduced size, low loss, frequency selective limiter devices that can be manufactured at low cost and that can operate with frequency selectivity over octave bandwidths while being operational at and above the microwave range without compromising dynamic range. The present invention is directed toward further solutions to address this need, in addition to having other desirable characteristics.

An embodiment of the present invention is directed to the design, fabrication, operation, and methods thereof, of lumped element frequency selective limiter (herein “LE-FSL”) devices and systems, which rely on miniature integrated circuit elements, i.e. lumped elements, to concentrate electromagnetic fields and provide significant differential attenuation of high power signals above a power threshold level, while mitigating the deleterious reduced-size effects associated with the lumped element design. For example, the reduced FSL ferrite-based material volume in a lumped element inductor (compared with an inductor that is not a lumped element) can result in reduced above-threshold power level absorption/attenuation relative to conventional elements and a dynamic range that is not sufficient for use in a number of applications. According to aspects of the present invention, reduced size affects are mitigated at least by increasing the active portion of the FSL device to enable operation at and above 1 GHz.

An embodiment of the present invention is directed to a device comprising a first lumped element inductor comprising a ferrite-based material. Above a selected threshold power level, a signal passing through the lumped element inductor is attenuated with frequency selectivity at select frequencies.

An embodiment of the present invention is directed to a device comprising a portion of conductive material and a portion of ferrite-based material. The portion of ferrite-based material is arranged proximal to the portion of conductive material, thereby, above a selected threshold power level, attenuating, at select frequencies, a signal passing through the device with frequency selectivity. An electrical length of the device is substantially less than a wavelength of the signal.

An embodiment of the present invention is directed to a method of manufacturing a device. The method comprises configuring a portion of conductive material and a portion of ferrite-based material in relation to each other such that, upon receiving a signal comprising a frequency at and above approximately 1 GHz, a signal passing through the device is attenuated with frequency selectivity.

An embodiment of the present invention is directed to a method for designing a device, the method comprising providing a mathematical model and using the mathematical model, thereby providing a frequency selective limiting device comprising a performance characteristic with approximately a pre-selected value. The method can further comprise incorporating a lumped element inductor comprising a ferrite-based material into the mathematical model and selecting an electrical length of the lumped element inductor to be substantially less than a wavelength of the signal passing through the lumped element inductor.

According to aspects of the present invention, an electrical length of the first lumped element inductor can be less than or equal to approximately 0.1 times a wavelength of the signal. The signal can have a frequency at and above approximately 1 GHz. The device can exhibit frequency selective power attenuation at frequencies at and above approximately 1 GHz. The device can be operable over a bandwidth of at least an octave. The device can be operable at frequencies at or above approximately 1 GHz. The device can be operable in the absence of frequency-dependent tuning of and/or selection of the device. The threshold power level can be selected to be a minimum near a center frequency of the device. According to aspects of the present invention, the device can comprise an area of less than approximately 100 mm² while exhibiting a limiting dynamic range of at least approximately 20 dB.

According to aspects of the present invention, upon receipt of a signal, a current flowing through a conductive portion of the lumped element inductor generates an RF magnetic field that couples to a spin system in the ferrite-based material, causing a frequency selective power attenuation of the signal.

According to aspects of the present invention, the signal below the selected threshold power level can be separated from the signal above the selected threshold power level by a quantity of power and/or amplitude larger than a product of the gyromagnetic ratio and the spin-wave linewidth of a material through which the signal passes, causing a frequency selective power attenuation of the signal.

According to aspects of the present invention, the device can comprise a second lumped element. According to aspects of the present invention, the second lumped element can be an inductor or a capacitor. The second lumped element can be configured relative to the first lumped element inductor in a cascaded configuration. The first lumped element and the second lumped element can be configured in the cascaded configuration according to threshold power level.

According to aspects of the present invention, the device can be integrated into an apparatus, such as a lumped element band-pass filter structure. The device can be integrated into a transmission line structure.

According to aspects of the present invention, the characteristic impedance of an LE transmission line can be decreased to approximately match an equivalent resistance representing power absorbed in the ferrite-based material by changing a capacitance of a second lumped element.

According to aspects of the present invention, the ferrite-based material can include a polycrystalline microstructure. According to aspects of the present invention, the ferrite-based material can be a ceramic ferrite-based material. According to aspects of the present invention, the ferrite-based material can exhibit an FMR linewidth no more than 20 times wider than that of a single crystal YIG film. According to aspects of the present invention, the ferrite-based material can exhibit a spin wave linewidth less than 10 times wider than that of a single crystal YIG film. According to aspects of the present invention, the ferrite-based material can exhibit a spin wave linewidth no more than 5 times wider than that of a single crystal YIG film.

A first surface of a first material and a second surface of a second material can be configured and arranged such that the first surface and the second surface are in intimate contact with each other; and wherein the first surface is a surface layer of the ferrite-based material and the second surface is a surface layer of the lumped element inductor.

According to aspects of the present invention, the portion of ferrite-based material can comprise a thin film and/or a line or point and can store energy. The portion of conductive material can be configured and arranged in the form of a solenoid coil, a toroid, a spiral, a square form, or combinations thereof. The portion of conductive material can be three-dimensional or confined to thin film or fewer dimensions, such as, for example, a line or point and can carry current.

According to aspects of the present invention the first lumped element and a second lumped element can be configured in a cascaded configuration. The first and the second lumped element in the cascade are configured in such a way that for signals at and above a frequency of approximately 1 GHZ a differential signal attenuation device can result.

According to aspects of the present invention, a step of configuring and/or arranging a first lumped element and a second lumped element can include processing techniques that can be selected from a group including microelectronic processing methods such as thin film deposition, lithography and etching, and/or techniques such as powder compaction, sintering, tape-casting and low temperature co-fired ceramic processing.

An embodiment of the present invention is directed toward LE-FSL devices and systems that can compensate for deleterious reduced-size effects on system performance by at least the structure, configuration and/or arrangement of the at least one lumped element inductor in a device and/or at least by the composition and/or microstructure of the at least one ferrite-based material.

According to aspects of the present invention, a threshold power level of the lumped element frequency selective limiting device can be less dependent on a spin wave linewidth of the ferrite-based material than a device that is not structured as a lumped element inductor.

According to aspects of the present invention, a plurality of lumped elements can be configured in a cascading configuration, increasing, for example, the limiting dynamic range relative to a non-cascaded design. The limiting dynamic range of an LE-FSL device, which can be small when the portion (or volume) of ferrite in the LE-FSL is small, can thus be extended.

According to aspects of the present invention, deleterious reduced size-effects can be mitigated by utilizing non-conventional ferrite-based LE-FSL materials that exhibit compositions and microstructures other than, and in addition to, single crystal YIG films or bulk ceramic ferrite-based materials.

Designing a lumped element further comprises fabricating a lumped element to produce a fabricated lumped element and measuring the value of the at least one performance characteristic for the fabricated lumped element. The mathematical model is refined, for example, by comparing the at least one target performance characteristic with the value of the at least one performance characteristic for the fabricated lumped element and iterating.

According to aspects of the present invention, the method can further comprise adding a second lumped element to the device. The method can comprise enabling a performance characteristic. The performance characteristic can be selected to be at least one of an increased target dynamic range, a lower target insertion loss, a lower target threshold power level, an increased target frequency selectivity and a target broad-band operation, wherein the enabled broad band operation is greater than existing systems of comparable size. The method can comprise defining a target threshold power level and a target dynamic range for the device.

According to aspects of the present invention, a proposed cascaded arrangement of at least two lumped elements can be structured. The mathematical model can be utilized in selecting the at least two lumped elements and structural and/or performance characteristics of each of the at least two lumped elements.

According to aspects of the present invention, a physical device corresponding to the target cascaded arrangement of the at least two lumped elements can be fabricated producing a fabricated device, and the threshold power level and dynamic range of the fabricated device can be measured.

According to aspects of the present invention, at least one of structuring, utilizing, fabricating and measuring steps can be repeated iteratively in order to attain a threshold power level and a dynamic range for the fabricated device that is substantially similar to the target threshold power level and dynamic range. Iterating can include repeating a first method step after performing a second method step to refine a match between the threshold power level and dynamic range for the lumped element frequency selective limiting device and the target threshold power level and dynamic range.

The structural and/or performance characteristics of the device can be selected to include at least one of a circumference of a portion of conductive material, a dimension of a portion of ferrite-based material and a number of lumped elements. At least one of a maximum circumference such as a length of a circumference of spiral portion of conductive material and a maximum dimension of the portion of ferrite-based material can be selected such that an electrical length of the device is substantially less that a wavelength of the signal. The at least one of a maximum circumference and a maximum dimension can be selected to be less than the electrical length of the device, rendering a propagation effect negligible.

The method can further include adjusting an impedance of the lumped element device. The method further can include adjusting a capacitance of a lumped element.

According to aspects of the present invention, an equivalent operational circuit and an input power required for operation can be defined for the device. An equivalent operational circuit can include at least a single lumped element. An equivalent operational circuit can include a lumped element capacitor. A structure of the device can be modified to attain a target equivalent operational circuit.

### BRIEF DESCRIPTION OF THE FIGURES

These and other characteristics of the present invention will be more fully understood by reference to the following detailed description in conjunction with the attached drawings, in which:

FIG. 1A is a top view of an embodiment of a ferrite-based lumped element inductor having a specific geometry, according to aspects of the present invention. The specific geometry can be, for example, a solenoid coil, a square coil, a toroid, and/or a planar spiral, with each inductor filled with a (biased) ferrite material in order to form the LE-FSL;

FIG. 1B is a side view of the embodiment of a ferrite-based lumped element inductor shown in FIG. 1A, according to aspects of the present invention;

FIG. 1C is a top view of another embodiment of a ferrite-based lumped element inductor having a specific geometry, according to aspects of the present invention;

FIG. 1D is an embodiment of a top view of a ferrite-based lumped element inductor having a specific geometry, according to aspects of the present invention.

FIG. 2A shows a circuit diagram associated with an embodiment of a cascaded LE-FSL structure having three LE-FSL elements (referred to herein also as sections), according to aspects of the present invention, having different threshold power levels;

FIG. 2B illustrates results for each of the three cascaded LE-FSL elements (or sections) having different threshold power levels corresponding to FIG. 2A;

FIG. 3A illustrates the calculated output power as a function of input power with the three LE-FSL elements of FIGS. 2A and 2B functioning at 4,030 MHz, according to aspects of the present invention;

FIG. 3B illustrates an embodiment, in top view, of a chip structure for one of the three cascaded LE-FSL sections associated with the data shown in FIGS. 2A and 2B;

FIG. 3C illustrates a side view of a section of the structure shown in FIG. 3B, according to aspects of the present invention;

FIG. 3D illustrates an embodiment, in top view, of a chip having a cascaded LE-FSL device structure, according to aspects of the present invention;

FIG. 4A is an illustrative embodiment, in top view, of a cascaded ferrite-based lumped element frequency selective limiter structure, where each inductor exhibits a 3-D coil-like geometry;

FIG. 4B is a side view illustration of the cascaded ferrite-based lumped element frequency selective limiter structure shown in FIG. 4A, according to aspects of the present invention;

FIG. 4C is an illustrative embodiment, in top view, of a cascaded ferrite-based lumped element frequency selective limiter structure having a 2-D coiled geometry on a ferrite-based substrate surface;

FIG. 4D is an illustrative embodiment, in side view, of the cascaded ferrite-based lumped element frequency selective limiter structure shown in FIG. 4C, according to aspects of the present invention;

FIG. 4E is an illustrative embodiment, in top view, of a cascaded ferrite-based lumped element frequency selective limiter structure having a modified 3D type coil-type geometry, the modified geometry of the structure is configured for reduced direct RF magnetic field coupling between each coil-like inductor structure, according to aspects of the present invention;

FIG. 5A is an equivalent circuit of a lumped element inductor, according to aspects of the present invention;

FIG. 5B illustrates an embodiment of a coil geometry used in an embodiment of a mathematical model enabling design of device structure for specific performance in a select application;

FIG. 5C is an embodiment of a set of material parameters used in the calculations; the material parameters are those of epitaxial YIG films;

FIG. 5D is an illustrative embodiment of a variation of a critical magnetic field strength with frequency, assuming the YIG parameters given in FIG. 5C and in internal field of 200 Oe;

FIG. 5E is an embodiment of an equivalent circuit of a lumped element transmission line section, according to aspects of the present invention;

FIG. 5F is an embodiment of an equivalent circuit of a lumped element transmission line section showing currents and voltages used in the model calculations, according to aspects of the present invention;

FIG. 6 illustrates a dependence on frequency of the power output as a function of power input;

FIG. 7 illustrates a variation of a resistance, the energy dissipated through generation of half frequency spin waves at power levels above threshold, as a function of input power using the parameters shown in FIG. 5C;

FIG. 8A is an illustration of the limiting dynamic range and threshold power level attainable with a transmission line impedance of approximately 50 Ohms at 8,020 MHz and an internal field of approximately 725 Oe, according to aspects of the present invention;

FIG. 8B is an illustration of the increased limiting dynamic range and decreased threshold power level attainable as the transmission line impedance, for a device otherwise substantially like that of FIG. 8A, is reduced from 50 Ohms to 25.0 Ohms, according to aspects of the present invention;

FIG. 8C illustrates a further increase in limiting dynamic range and decrease in threshold power level attainable as impedance for a device otherwise substantially like that of FIGS. 8A and 8B is further reduced to 12.5 Ohms at 8,020 MHz;

FIG. 9 is an illustrative embodiment of the variation of the S-parameter, S₁₂, with frequency for different lumped element transmission line impedances;

FIG. 10 is an illustrative embodiment of the calculated output power as a function of input power at four frequencies over the range 6,000 MHz-12,000 MHz with an impedance of 12.5 Ohms and a critical magnetic field that is approximately equal to 10 times that of YIG;

FIG. 11A is an illustrative embodiment of a flow chart associated with the design process for an LE-FSL device according to aspects of the present invention; and

FIG. 11B illustrates intermediary design steps, according to aspects of the present invention.

### DETAILED DESCRIPTION

An illustrative embodiment of the present invention relates to an LE-FSL device operable at and above frequencies corresponding to the microwave range that exhibits frequency selective power attenuation for a signal above a threshold power level. Upon receipt of a broadband signal above and below a selected threshold power level, according to aspects of the present invention, the LE-FSL device differentially attenuates the signal in such a way that at select frequencies the signal above a selected threshold power level is attenuated while the signal within a pass-band below a selected threshold power level is substantially passed through. An illustrative embodiment of the present invention relates to a method for device design and manufacture and to an apparatus that incorporates the LE-FSL device, which attenuates an above threshold power signal with frequency selectivity for example for improved performance and/or reduced size applications requirements.

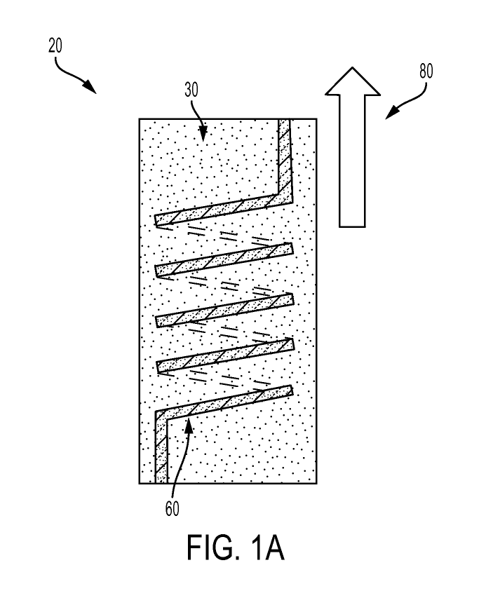

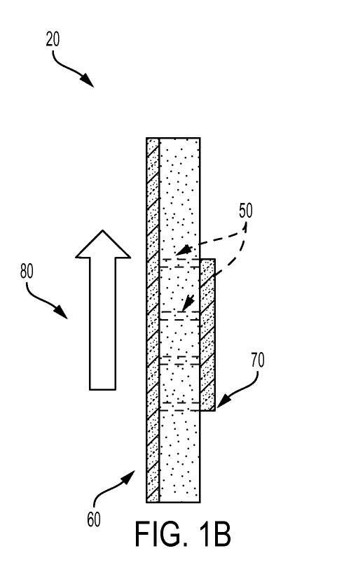

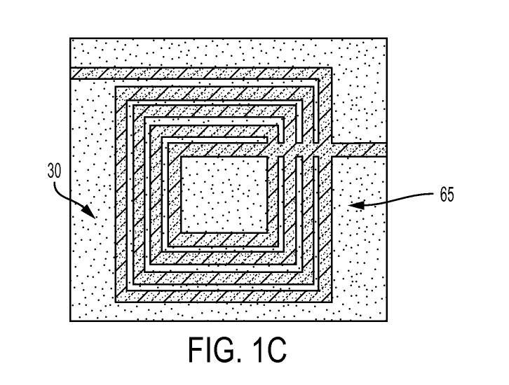

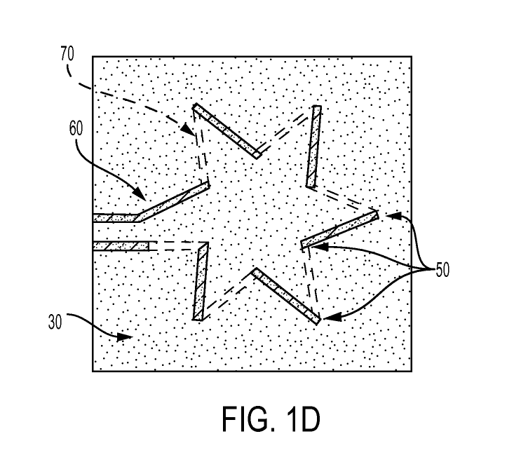

FIGS. 1A through 11B, wherein like parts are designated by like reference numerals throughout, illustrate an example embodiment or embodiments of devices incorporating LE-FSLs, according to the present invention. Although the present invention will be described with reference to the example embodiment or embodiments illustrated in the figures, it should be understood that many alternative forms can embody the present invention. One of skill in the art will additionally appreciate different ways to alter the parameters of the embodiment(s) disclosed, such as the size, shape, or type of elements or materials, in a manner still in keeping with the spirit and scope of the present invention.

An embodiment of a lumped element inductor 20 is illustrated in FIGS. 1A-1B. According to aspects of the present invention, the lumped element inductor 20 can be in the form of a 3-D solenoid coil having a ferrite-based material 30 provided in the form of a YIG substrate. The lumped element inductor 20 can have a portion of conductive material 65 which can include a top metal 60, a bottom metal 70, and a via 50, which can be plated. A direction of a magnetic field 80 can be oriented along an axis of symmetry of the lumped element inductor 20. FIG. 1A illustrates a top view of the lumped element inductor 20, while FIG. 1B is a side view of the lumped element inductor 20.

In accordance with an embodiment of the present invention, the geometry (shape or form) of the lumped element inductor 20 can be of a 2-D spiral comprising a top metal 60 on a surface of a substrate of ferrite-based material 30 as illustrated in an embodiment in FIG. 1C, and of a 3-D toroid as illustrated in an embodiment in FIG. 1D. The ferrite-based material 30 can be in a form of a thin film and can comprise a single crystal microstructure and have a composition such as YIG.

The performance of a lumped element inductor 20, which, according to aspects of the present invention, can be described in terms of operational parameters such as threshold power level 225 and limiting dynamic range 335, can depend on a plurality of variables. According to aspects of the present invention, these variables can include at least spatial features (design, structure, geometry, structural features) for the lumped element inductor and properties of the materials used in the lumped element inductor 20. Since microstructure and composition of a material can affect material properties, the material(s) used for the portion of conductive material 65 and the material(s) used for the portion of ferrite-based (magnetic) material, as well as their dimensions and the number and type of repeat units, can be selected to attain target performance values for specific operating parameters.

In an embodiment of the present invention, the spatial features of the lumped element inductor 20 can be selected to provide higher RF magnetic fields for a given current (and thus produce a lower threshold power level 225) than does a device that is not configured and dimensioned as a lumped element inductor 20, for example a stripline structure. The structure of the lumped element inductor 20 produces a lower threshold power level 225 using higher spin wave linewidth materials than can be achieved in a stripline structure. The structure of the lumped element inductor 20 forms the basis of an LE-FSL device 10 with a threshold power level 225 that is less dependent on materials properties than are devices that do not comprise lumped element configurations. As such, ceramic ferrites with spin wave linewidths of more than 10 Oe can be used operationally in an LE-FSL device 10.

An embodiment of a resulting LE-FSL device 10 is operable at frequencies at and above approximately 1 GHz. The term approximately is not intended to further limit frequencies at which the device is operable, but, rather the term approximately is intended to extend frequencies at which the device is operable to include a value above and below 10% of a claimed value. An RF magnetic field induced by the portion of conductive material 65 penetrates at least a portion of the ferrite-based material 30. The portion comprises a volume of material arranged proximal to and/or within the portion of conductive material 65 and can be bounded by a transverse dimension of the portion of conductive material 65. The portion of conductive material 65 (referred to herein also as inductive material) can be in a coiled form. A first surface layer, that of the ferrite-based material 30, and a second surface layer, that of at least a portion of the conductive material 65 are configured and arranged such that the first surface and the second surface are in intimate contact with each other.

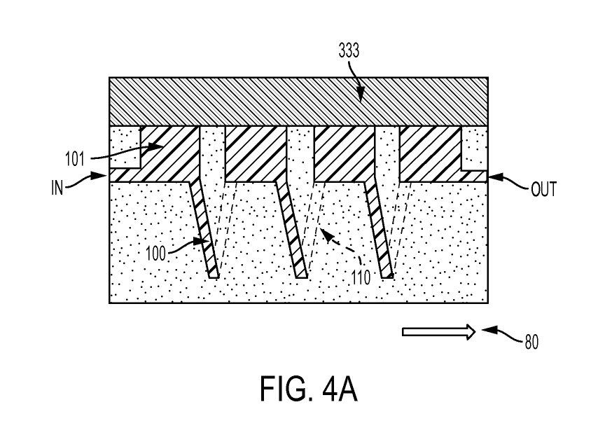

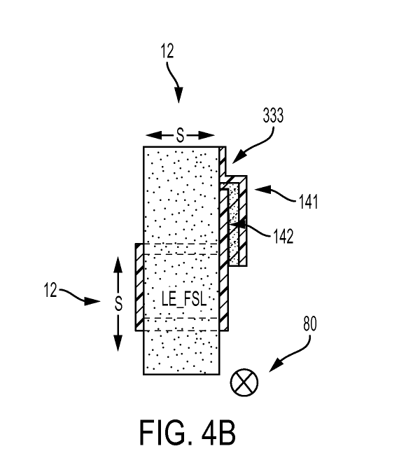

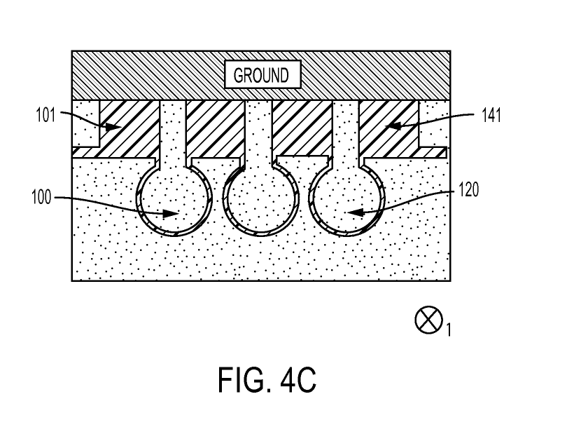

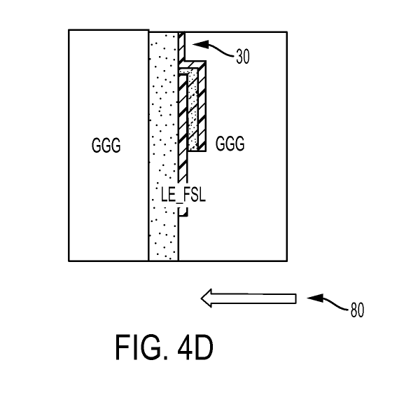

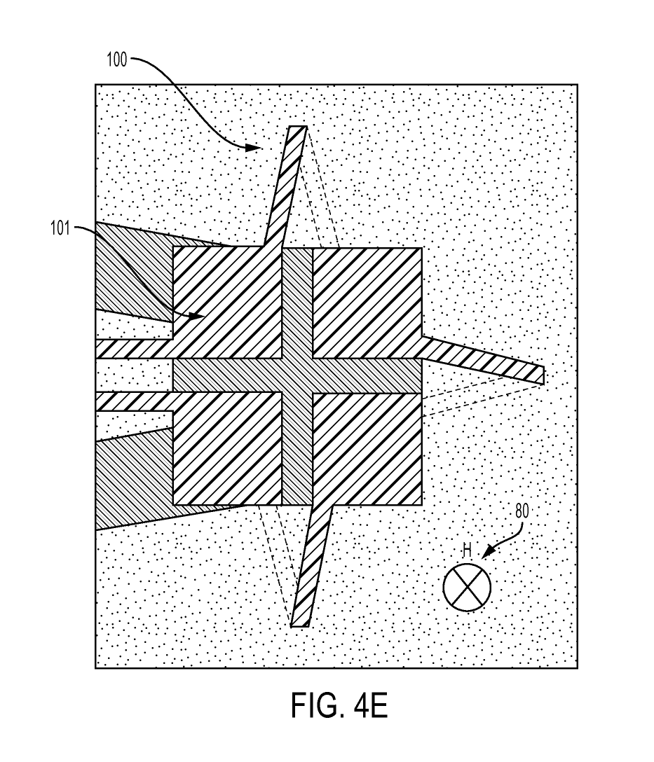

Non-conventional LE-FSL ferrite-based materials 30 also enable the design and manufacture of devices that can be embedded in reduced size systems and can offer a number of manufacturing, operational and performance advantages over FSLs utilizing single crystal YIG or conventional bulk ceramic ferrites. Ceramic ferrite films, for example, can be produced at lower cost and can make manufacturing easier than, for example, single crystal YIG films. Multilayer tape-casting techniques make it easier to produce a via 50 in a ferrite-based material 30 as is required, for example, for the structure shown in FIG. 4A.

Techniques such as multilayer-tape casting also promote intimate contact between a top layer of the ferrite-based material 30 and the portion of conductive material 65 (a conducting coil or coil-like shape). Good contact becomes increasingly important as the active volume (associated with the ferrite-based material 30) is increased due to the increased contact area between the conductive material 65 (e.g. in coiled form) and the ferrite-based material 30 layer.

An embodiment of a ferrite-based material 30, ceramic ferrites, can exhibit polycrystalline microstructures which can be made to have FMR and spin wave linewidths approaching those of single crystals and/or substantially similar to those of single crystals, for example a single crystal YIG film, by optimizing composition and processing temperatures. For ferrite-based material 30 thicknesses of approximately 50 μm and greater, a ferrite-based material 30 comprising a ceramic ferrite can be produced with techniques such as powder compaction and sintering, tape-casting or low temperature co-fired ceramic (LTCC), although thin film techniques can also be used. Alternative ferrite-based material 30 such as lithium ferrite can be advantageous in that they can exhibit higher saturation magnetization than YIG, increasing the limiting device dynamic range at high microwave frequencies.

Ceramic FMR and/or spin wave line widths can be made to approach those of single crystals (for example single crystal YIG) by adjusting the composition to minimize the crystal anisotropy of the fields and by adjusting the composition and the annealing conditions so as to increase the ceramic grain size while maintaining low porosity. This can increase magnetic homogeneity of the ceramic ferrite-based material and reduce the FMR and spin wave line widths. The ferrite-based material can include a ceramic portion that can exhibit a polycrystalline microstructure and can have an FMR line width of no more than 20 times that of a single crystal YIG film and a spin wave line width of less than 10 times that of a single crystal YIG film. According to aspects of the present invention, the ferrite-based material can have a spin wave line with of no more than 5 times that of a single crystal YIG film.

The ferrite-based material 30 can be selected from a non-conventional ferrite-based material group that includes but is not limited to a lithium ferrite or ceramic ferrite, in thin film single crystalline and/or polycrystalline form or, as one of skill in the art will recognize, in any one of a variety of alternative forms, structures, microstructures, and compositions. These can include, for example, composite materials, such as those described in U.S. application Ser. No. 13/466,751, filed May 8, 2012, the entire teachings of which are incorporated herein by reference. Also, for example, ferrites with higher saturation magnetization, such as lithium ferrite, can increase limiting range at high microwave frequencies and use of ceramic ferrites can result in lower cost more producible devices.

LE-FSL processing can exploit microelectronic technology techniques to attain ferrite-based lumped element inductor 20 forms, microstructures, and compositions that enable operation at high frequencies (used interchangeably herein with high frequency operation). During operation at low frequencies (used interchangeably herein with low frequency operation) the ferrite-based material 30 can be in a rod form and the conductive portion of the inductor (e.g. a solenoid inductor) can be a mechanically wound coil.

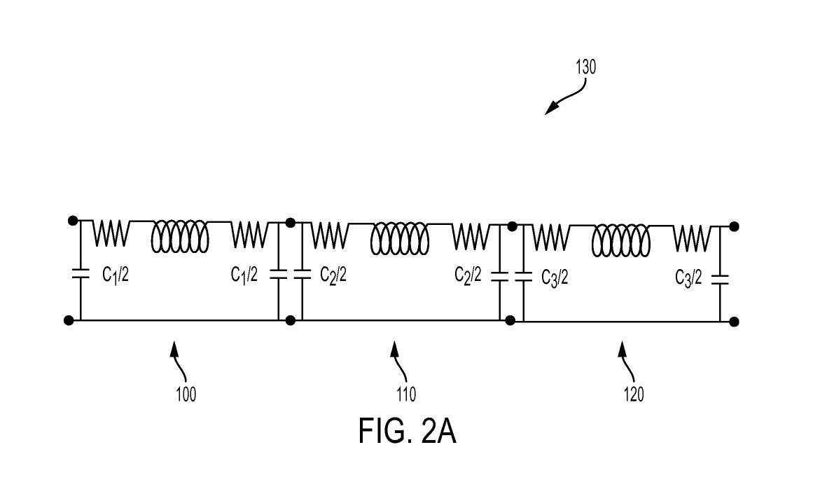

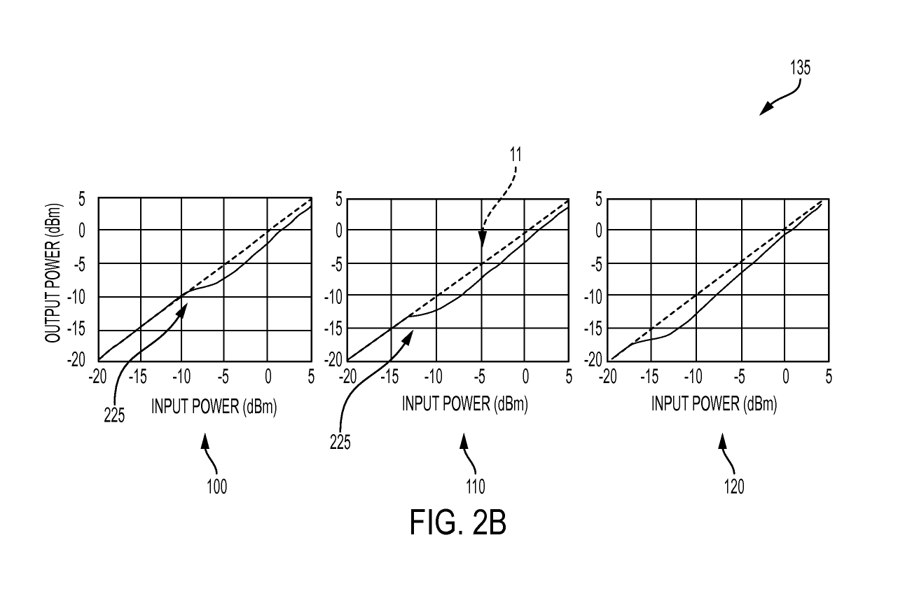

A diagram shown in FIG. 2A illustrates an embodiment of a circuit-equivalent of a first lumped element FSL section 100, a second lumped element FSL section 110, and a third lumped element FSL section 120 configured in a cascaded LE-FSL 130 configuration. A cascaded LE-FSL configuration 130 enables integration of lumped elements into, for example, LE transmission lines that exhibit a useful limiting dynamic range 335 while adhering to potentially tight physical space limitations of the LE transmission line system.

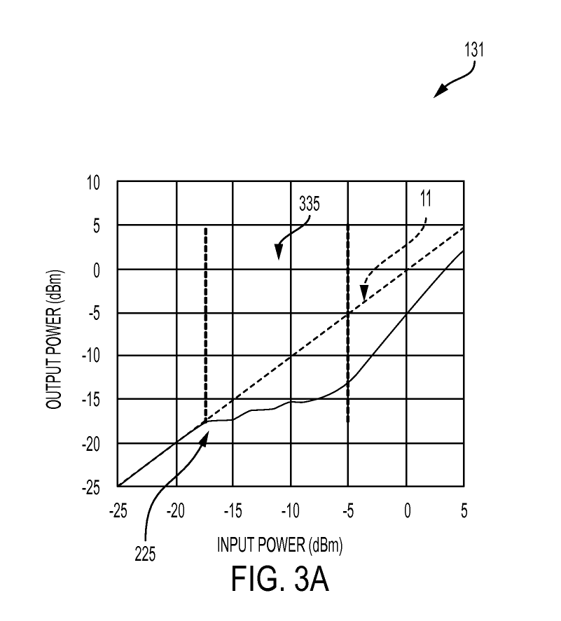

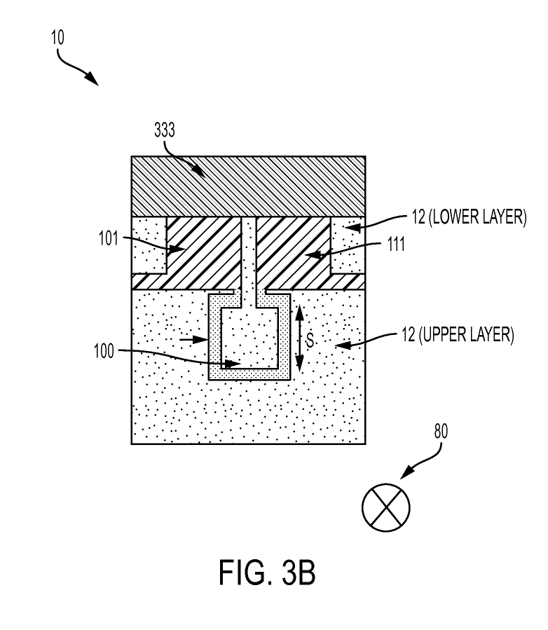

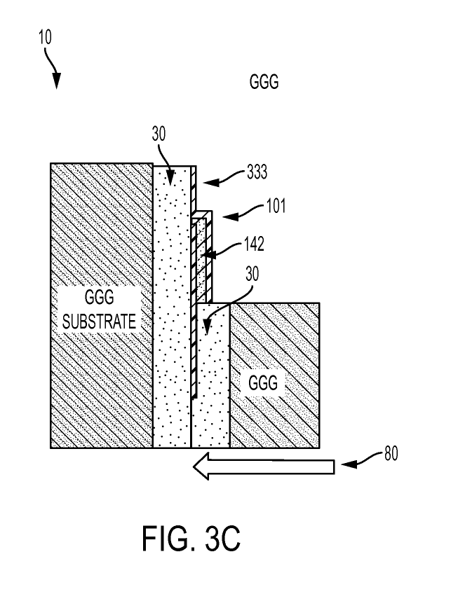

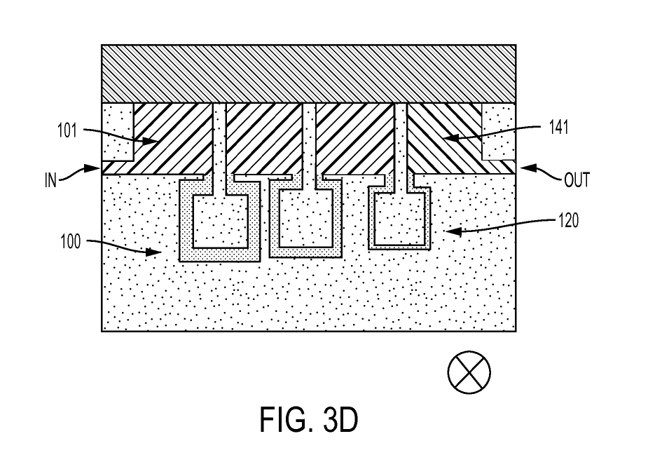

FIG. 2B depicts example experimental data 135 illustrating a dynamic range that is attained with each of the individual LE-FSL sections 100, 110, 120 shown in FIG. 2A, according to aspects of the present invention. In an embodiment depicted in FIG. 2B, the three LE-FSL sections 100, 110, 120, each exhibiting different threshold power levels, are configured in a cascade configuration in order of threshold power level 225. The LE-FSL section 100 exhibiting the highest threshold power level 225 is configured proximal to the input of the device, while the LE-FSL section 120 exhibiting the lowest threshold power level 225 is configured proximal to the output of the device. In the example embodiment, the threshold power level 225 for each LE-FSL section is varied by varying a width, w, of the portion of conductive material 65 of the lumped element inductor 20 (see FIG. 3B). In this example, the width of the conductive portion and the dimension, s, of the volume of ferrite-based material (and the threshold power level 225), respectively, for LE-FSL section 100 is 60 μm, 389.2 μm (−9 dB), for LE-FSL section 110 is 40 μm, 342.9 μm (−13 dB), and for LE-FSL section 120 is 25 μm, 300 μm (−17 dB).

FIG. 3A illustrates the calculated output power as a function of input power for an embodiment of cascaded LE-FSL sections 100, 110, 120 shown in FIG. 2A at 4,030 MHz. In this example, the limiting dynamic range 335 is extended to approximately 12 dB for the cascaded LE-FSL compared with approximately 4 dB for each LE-FSL section 100, 110 and 120. The reference line in FIG. 3A corresponds to 0 dB. FIG. 3B is an embodiment of a structure of an LE-FSL section 110.

As an example, a six section LE-FSL cascade containing seven thin film capacitors with value between 0.1 and 0.2 pF, each measuring 200 μm×200 μm, and six planar LE-FSL inductors having an effective radius of 200 μm would occupy an area of a few square millimeters. Comparison of results attained with strip-line FSLs indicated that size reductions in the range of 10 to 100 times appear possible with cascaded LE-FSL sections.

A top view of an embodiment of a device 10 comprising a cascade of LE-FSL sections is illustrated in FIG. 4A. According to aspects of the present invention, the device 10 can include a plurality of LE-FSL sections 100, 110 and 120 configured as a 3-D coil in combination with a ferrite-based material 30 substrate and a plurality of a via 50. The thickness of the ferrite-based material 30 substrate can equal the length of the dimension, s, of the effective coil side (the portion of conductive material 65). A ceramic ferrite-based material 30 can be used in the 3-D coiled structure LE-FSL sections 100, 110 and 120 depicted in FIG. 4A. While a single crystal YIG film can be used as the ferrite-based material 30, ceramic materials can provide an alternative ferrite-based material 30 that is easy to machine and to process and that offers a number of advantages for, including but not limited to, device structures that include vias. However, most commercial ceramic ferrites have FMR linewidths that are 100 times wider than single crystal materials and spin wave linewidths that are at least ten times wider, precluding their use in such applications. In FIG. 4B a side view of the cascaded LE-FSL device 10 depicted in FIG. 4A is illustrated.

The LE-FSL device 10 comprising a plurality of lumped element inductors 20 configured in a cascaded configuration can also include a plurality of lumped element capacitors 101, 111, 121 and 141. Lumped element capacitors 101, 111, 121 and 141 can be formed with a thin film dielectric 142 (see, e.g., FIG. 4B) such as SiO₂. The area of the thin film dielectric 142 in a parallel plate capacitor is proportional to the dielectric thickness required to withhold the maximum anticipated voltage and inversely proportional to the dielectric constant. Interdigital capacitors can be used and may be simpler to implement at high frequencies. Parallel pumping of the spin waves results with the magnetic bias 80 co-linear with the axis of the coils of the portion of conductive material 65, as indicated in FIG. 4A.

One of skill in the art will recognize that alternative modes of operation of device 10 are possible. For example, if RF magnetic field coupling between adjacent coils is a concern, the portion of conductive material 65 can be oriented as shown in FIG. 4E. In FIG. 4E an embodiment of device 10 is modified for reduced direct RF magnetic field coupling between coiled portions of conductive material 65 of the LE-FSL sections 100, 110 and 120, relative to, e.g. an embodiment depicted in FIGS. 4A-4D. In FIG. 4E, the magnetic bias 80 is shown normal to the ferrite-based material 30 surface resulting in perpendicular pumping.

In FIGS. 4C-4D, a top view and a side view, respectively, are shown of a LE-FSL device 10 comprising a plurality of lumped element inductors in a cascaded configuration. The structure of each lumped element inductor 20 can comprise a 2-D coil-like geometry of the portion of conductive material 65 on a ferrite-based material 30 substrate surface. The device 10 structure shown in FIG. 4C, with the lumped element inductors 20, having a 2D circular coiled form, minimizes material processing requirements because the simplified 2D design can eliminate the need for a number of microfabrication steps. For example, since the processing is performed on one surface of the ferrite-based material 30, the need for a via 50 that extends through the ferrite-based material 30 is eliminated. One of skill in the art will appreciate that, in this case, YIG thin films can be the ferrite-based material 30. The effective volume of the YIG ferrite-based material 30 film, and hence the limiting dynamic range 335, can be doubled by adding a second YIG ferrite-based material 30 in a film form as shown in FIG. 4D. This can require etching of the second YIG ferrite-based material 30 film surface to accommodate the thickness of the capacitor and prevent spacing from the coil-like portion of conductive material 65.

An LE-FSL device 10 can contain a plurality of lumped elements, including at least one of a lumped element inductor 20 and a lumped element capacitor 101. With a desired dynamic range defined for the cascaded LE-FSL device 10 structure, the number of lumped element inductors 20 needed to achieve this limiting dynamic range 335 can be determined by determining the threshold power level 225 and limiting dynamic range 335 associated with each LE-FSL section, starting with the LE-FSL section with the lowest threshold power level 225. The number of capacitors can be determined by the requirements of the lumped element transmission line, band-pass filter, or other apparatus in which the LE-FSL device 10 is embedded. For example, an LE transmission line can be formed from cascaded pi networks so that the number of capacitors equals the number of inductors plus one. The capacitors at the input and the output can have values equal to one half of the capacitors configured between inductors. The characteristic impedance of a system such as an LE transmission line, in which an LE-FSL is embedded, can be reduced by increasing the capacitance of a lumped element capacitor in the LE-FSL device.

While a cascaded LE-FSL device 10 structure is illustrated in FIGS. 4A-4E, one of skill in the art will recognize that a single LE-FSL section 100 can be used in lieu of the cascaded LE-FSL 130 resulting in an operable single lumped element or single lumped element-equivalent LE-FSL device 10.

The cascaded LE-FSL device 10 can be used as an inductor exhibiting a power dependent loss in a variety of circuits, including but not limited to circuits such as LC resonators, filters and impedance transformers. It can also be used in a lumped element transmission line (LETL) and can act as a low pass filter.

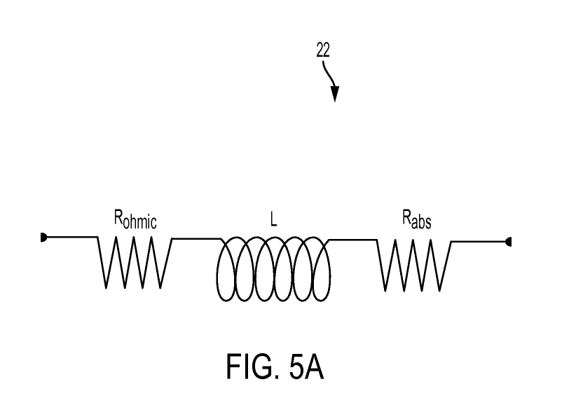

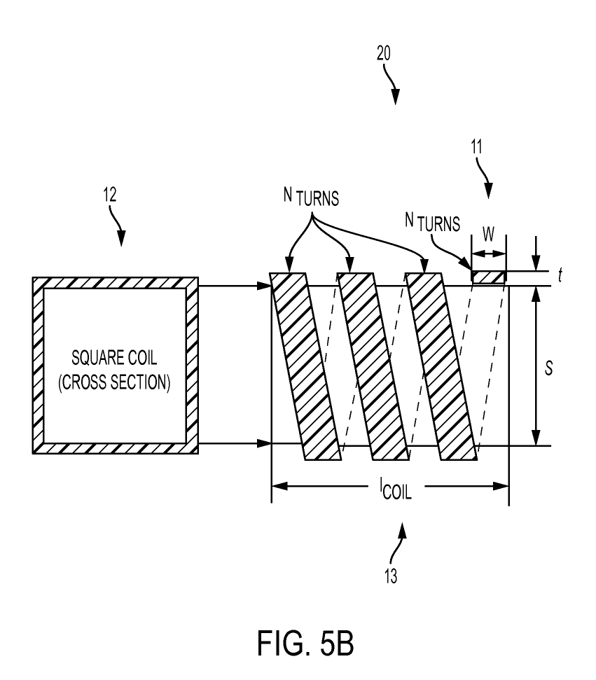

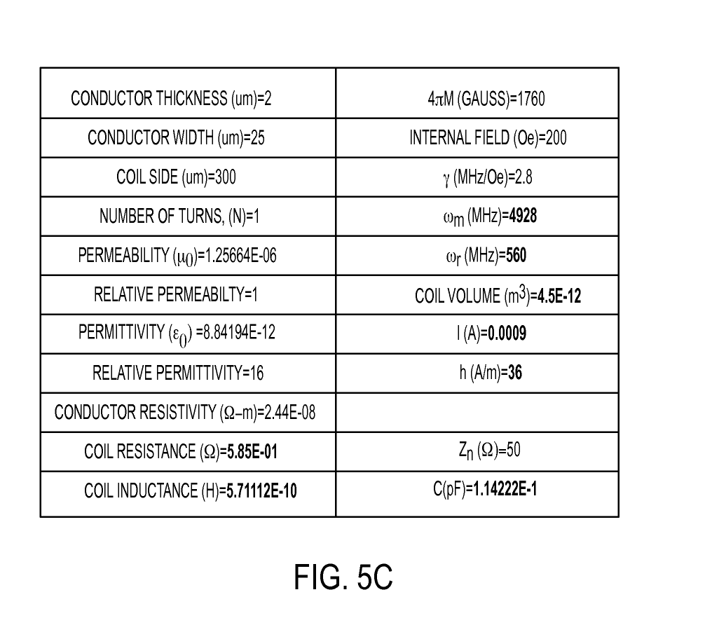

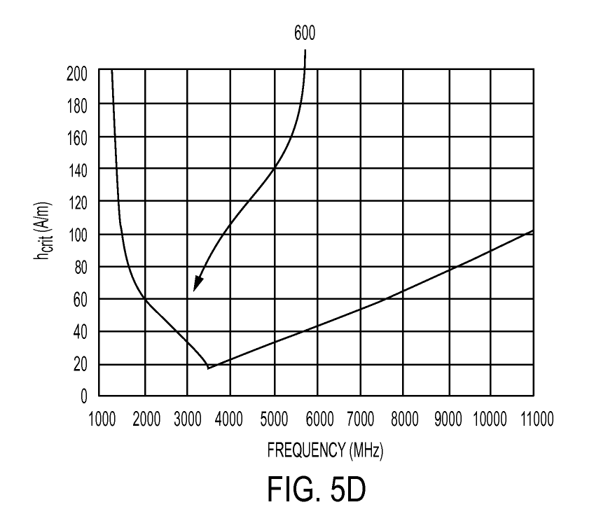

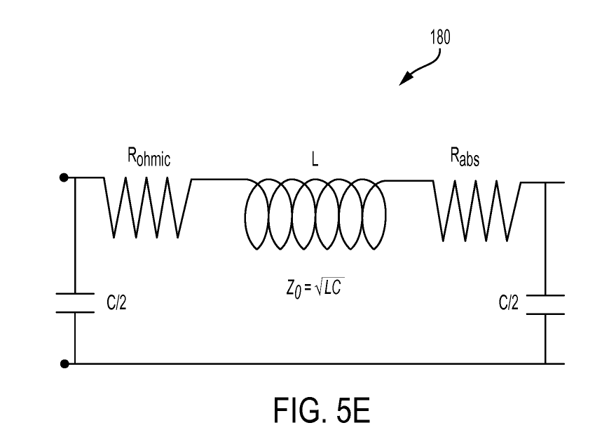

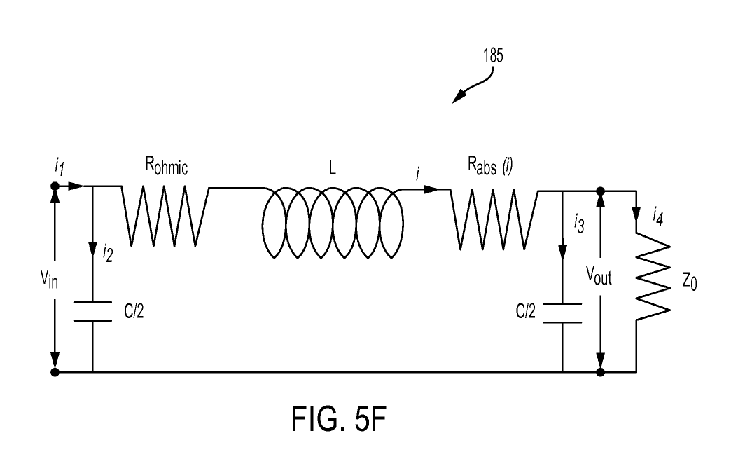

FIG. 5A illustrates an embodiment of an equivalent circuit of a lumped element inductor 22. FIG. 5B illustrates a corresponding schematic of the geometry of the lumped element inductor 20 (used in calculations with the mathematical model, according to aspects of the present invention), and FIG. 5C illustrates a list of parameters (in this example for YIG) used in the calculations, according to aspects of the present invention. A resulting variation 600 in the critical magnetic field as a function of frequency is shown in FIG. 5D.

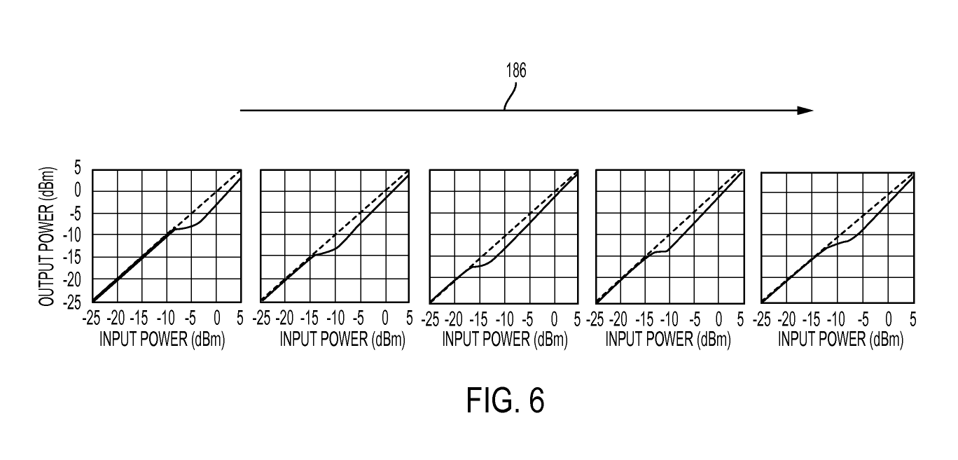

FIG. 5E is an equivalent circuit of a lumped element transmission line section 180 incorporating a lumped element frequency selective limiter section 100 in combination with at least one lumped element capacitor 101, according to aspects of the present invention. Current through the coiled portion of conductive material 65 can be treated as an independent variable, and the input and output power from an LE-FSL transmission line section 180 can be calculated for any current through the LE-FSL device 10, according to aspects of the present invention. An LE-FSL transmission line section showing operating conditions 185, such as currents and voltages used, such as voltage in, Vᵢₙ, and voltage out, Vₒᵤₜ, is shown in FIG. 5F. FIG. 6 illustrates power output as a function of power input 186 with parameters given in FIG. 5C at five frequencies over the 2,000 MHz to 6,000 MHz range: 2030 MHz, 3030 MHz, 4030 MHz, 5030 MHz and 6030 MHz, respectively, with increasing frequency in the direction of the arrow 186.

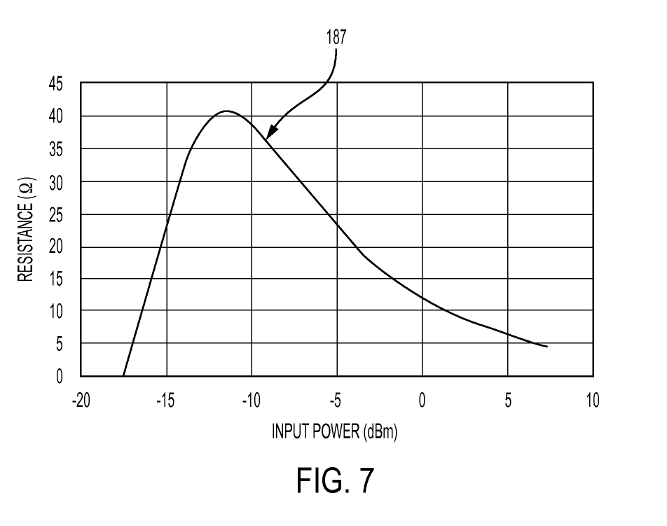

According to aspects of the invention, the threshold power level 225 for an LE-FSL device 10 can be selected to be a minimum near the center range (of frequency for the frequency selective limiter). Output power as a function of input power, shown in FIG. 6, using the same parameters as in FIGS. 5C and 5D demonstrates this. This is also consistent with the variation of the critical value of the RF magnetic field with frequency, as shown in FIG. 5D and with the behavior of a resistance (representing energy dissipation at power levels above threshold) with input power 187, as shown in FIG. 7.

The limiting dynamic range 335, which can be small when the volume of ferrite-based material 30 in the LE-FSL is small, can be extended by cascading LE-FSLs.

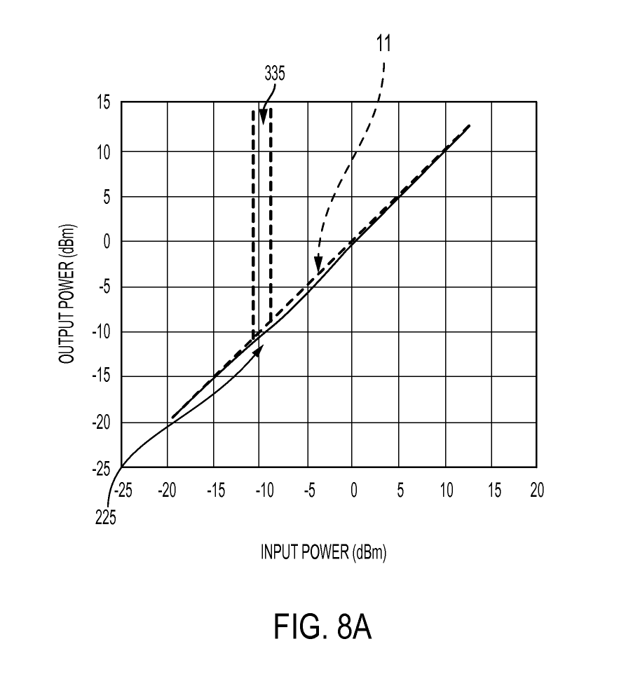

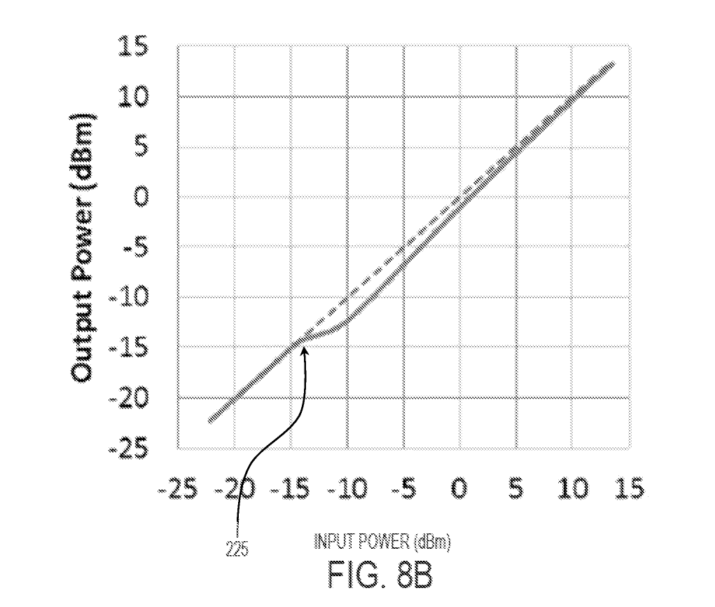

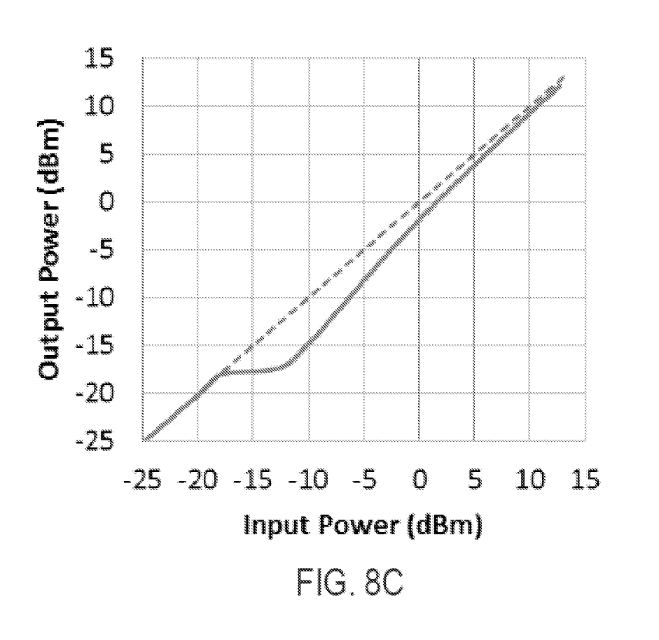

FIGS. 8A to 8C illustrate the effect of impedance matching of a transmission line on limiting dynamic range 335 and threshold power level 225 of the device 10. Impedance matching refers to decreasing the characteristic impedance of the LE transmission line to values more compatible with the resistance representing energy dissipated substantially within the ferrite-based material 30 at power levels above threshold. The power output is calculated as a function of input power for an LE-FSL device 10 structure operating at 8,020 MHz with an internal field of 725 Oe for operation between 6,000 MHz and 12,000 MHz. The dimension, s, is approximately 156 microns, maintaining the electrical length less than 1/10 the wavelength at 12,000 MHz (parameters are otherwise those in FIG. 5C).

FIGS. 8A-8C show that the limiting dynamic range 335 can improve significantly with a decrease in the characteristic impedance, z₀, of the LE transmission line 180, according to aspects of the present invention. FIG. 8A illustrates a limiting dynamic range 335 and a threshold power level 225 attainable with a transmission line impedance of approximately 50 Ohms. Impedance values are successively halved in value from FIG. 8A to FIG. 8C. In FIG. 8B the transmission line impedance is reduced from 50 Ohms to 25.0 Ohms at 8,020 MHz with an internal field of approximately 725 Oe. In FIG. 8C increased limiting dynamic range 335 and decreased threshold power level 225 is further attainable as transmission line impedance is reduced to 12.5 Ohms at 8,020 MHz with an internal field of approximately 725 Oe (see FIG. 3A). The reference line 11 corresponds to zero dB.

The device 10 shown in FIG. 8A has approximately a four times reduction in a volume of the portion of ferrite-based material 30 (e.g. the YIG volume proximal to and bounded by the portion of conductive material 65, the portion of ferrite based material 30 in which a magnetic field is induced when a current flows through the portion of conducting material). The limiting dynamic range 335 is low, approximately 1 dB. The limiting dynamic range 335 can be increased by cascading a plurality of LE-FSL sections, as illustrated in FIG. 3A. Additionally and alternatively, the limiting dynamic range 335 can be increased by decreasing the characteristic impedance of the transmission line 180 to approximately match the equivalent resistance representing the power absorbed by the ferrite-based material. The characteristic impedance of the LE transmission line 180 can be made more compatible with the energy dissipated through generation of half frequency spin waves at power levels above threshold by increasing a capacitance in the transmission line. According to aspects of the present invention, this can be done by increasing a capacitance in the lumped element transmission line 180 section to attain a desired ratio between an inductance, L, of the lumped element inductor and the capacitance, C, of at least one capacitor 101 of the transmission line section (square root of the inductance divided by the capacitance) matches a target desired value of the characteristic impedance, z₀, as shown, according to aspects of the present invention, in FIG. 5E. FIGS. 8A-8C show that the limiting dynamic range 335 can improve with decreasing characteristic impedance.

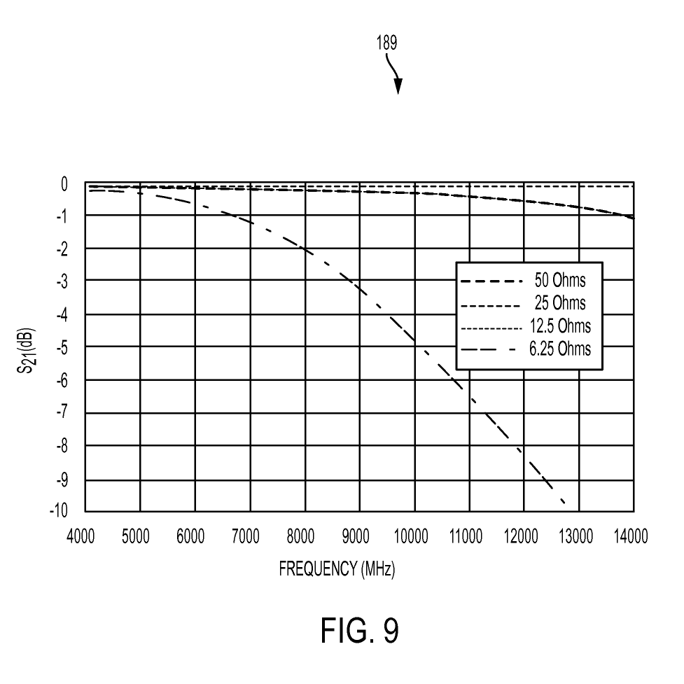

Increasing the capacitance of at least one capacitor 101 of the transmission line section 180 can decrease a cut-off frequency 189, as shown in FIG. 9 for a characteristic impedance of 50 Ohms, 25 Ohms, 12.5 Ohms and 6.25 Ohms. The decrease in cut-off frequency can be significant, e.g. at 6.25 Ohms, and can become less marked as the characteristic impedance increases, e.g., to 50 Ohms. The variation of an S-parameter, S₁₂, as a function of frequency for each of four LE transmission line impedances is shown in FIG. 9, according to aspects of the present invention.

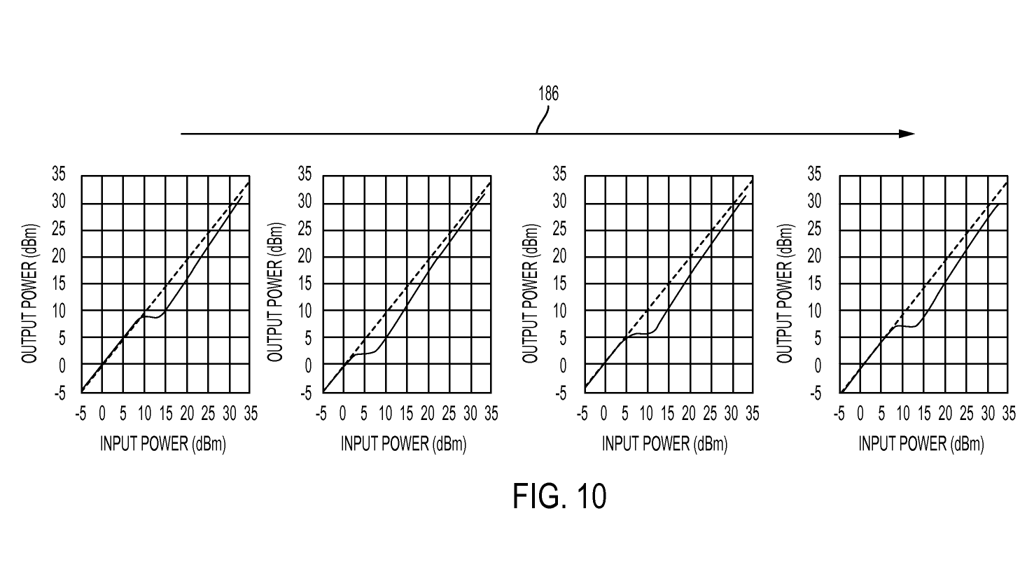

FIG. 10 illustrates, for an impedance of 12.5 Ohms and a critical magnetic field approximately ten times that of YIG, the effect of frequency on operating performance 190, for an example embodiment, according to aspects of the present invention, by illustrating calculated power output as a function of power input at each of four frequencies, 6,000 MHz, 8,000 MHz, 10,000 MHz and 12,000 MHz.

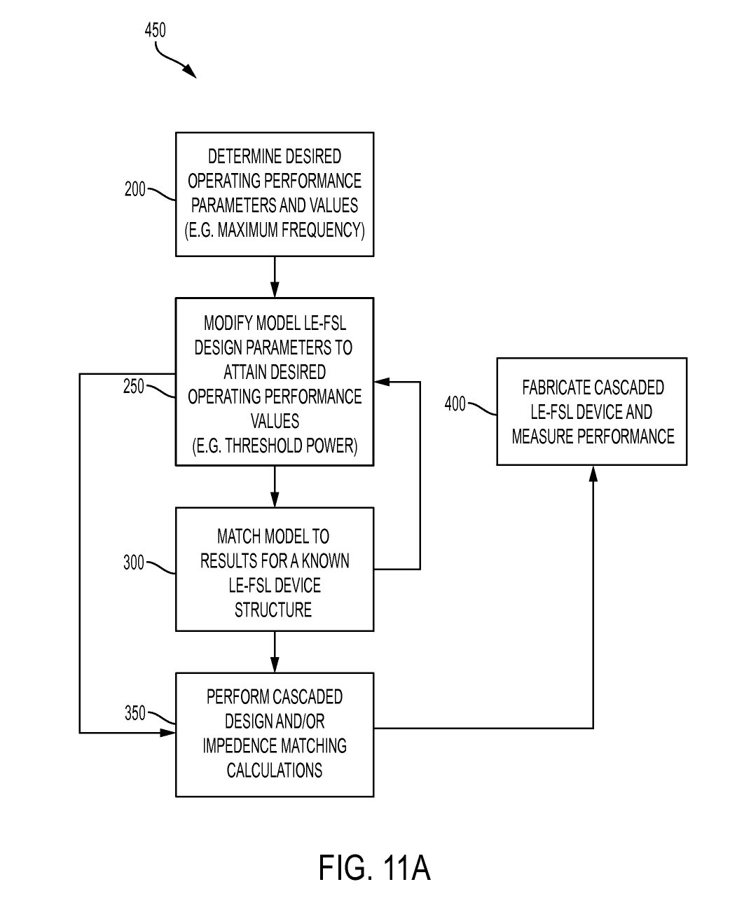

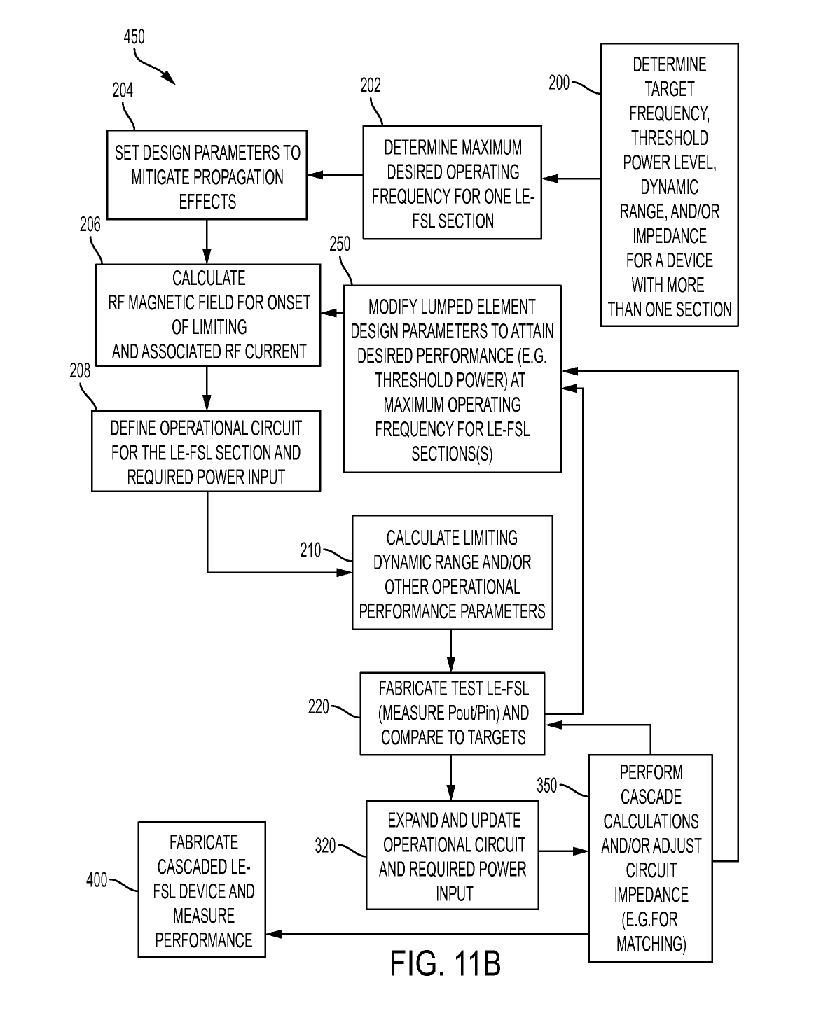

FIGS. 11A and 11B illustrate in flow chart form an embodiment of a design process 450 that can be used to tailor and maximize cascaded LE-FSL device 10 operating performance for a particular application. Lower power threshold levels are anticipated using this method than without using this method at least since an effective radius of a conductive coil, related to a dimension (a width) of the portion of ferrite-based material 30, can be reduced within the limits of the fabrication process without significantly affecting the insertion loss since a length of the portion of conductive material 65 (circumference of the coil) is small. The method can enable the design of devices that, in accordance with aspects of the present invention, can be operational over at least an octave bandwidth in the 1000 MHz to 12,000 MHz range and can provide a limiting dynamic range 335 of greater than 20 dB with reductions in area of 1-2 orders of magnitude.

According to aspects of the present invention, in a first step 200, a target operating parameter or operating parameters with values describing operating performance can be determined.

An example of an operating parameter can be a maximum desired operating frequency or wavelength for example for an LE-FSL section 100 comprising the portion of conductive material 65 on and/or embedded in the ferrite-based material 30, backed by a ground plane 333 (step 202). A target performance value for the operating parameter can be selected for a specific application. During execution of a plurality of steps, a maximum circumference of a Single Turn of the Portion of Conductive Material 65 can be Set to be Less than approximately 1/10^{th} of the corresponding signal wavelength (this sets the maximum effective radius of a single turn of the portion of conductive material 65 in a coil-like configuration; step 204). The critical RF magnetic field required for the onset of frequency selectivity and the RF current can be determined (step 206). The operational circuit (the circuit in which the LE-FSL section is to operate) and a required input power can be defined, thus determining the threshold power level 225 (step 208).

Once the target operating parameter or parameters and values is set, an iterative process to match model design parameters/variables and performance values for operating parameters can be initiated. The iterative process can include comparison of the performance values for operating parameters in a modeled device with the target operating performance values (step 210). During model calibration, a tweaking of the model to match values output from fabricated test devices can be performed. During device design, performance values for a model device with specific design parameters can be compared with target performance values for operating parameters and/or with performance values for a fabricated device (step 220). For example, design parameters (e.g. radius, width of conductive portion, impedance of circuit) can be modified to attain the target threshold power level 225. Design parameters can be refined until the target threshold power level 225 is attained (step 250).

Once the LE-FSL model design parameters for the target threshold power level 225 are calculated, the power out as a function of power in and the limiting dynamic range 335 for a single element and/or a single-element-equivalent LE-FSL device 10 can be calculated. A test LE-FSL device 10 can be fabricated (step 220). In an embodiment, measurements of operating parameter performance that can be compared with the calculated data, such as but not limited to power out as a function of power in and limiting dynamic range 335, are made on the test device. Measured data are compared with calculated data, and, in an iterative process, a relation between LE-FSL device 10 design parameters and operating parameters and performance values can be refined (step 250).

In accordance with an example embodiment, the iterative process can be a matching process in which model design parameters/variables and operating parameter performance for a cascaded LE-FSL device 10 having the power output of a single element and a single-element-equivalent LE-FSL equivalent circuit comprising multiple sections and/or elements are substantially matched. For example, once a match is approximately attained, additional elements and/or sections can be added into the design process. Approximately refers herein to a value that lies within 10%, inclusive, of the target value: The operational circuit can be expanded and updated (step 320). Calculations to attain target operating performance parameters (i.e. target performance values for specific operating parameters) for a complex device having a cascaded configuration and multiple sections and elements can be conducted (350). Calculated values can be matched to target values by iterating through a series of process steps, including but not limited to those described above, in various orders and combinations.

For example, according to aspects of the present invention, in a design process step 350, the number of LE-FSL coils and/or sections 100, 110, 120 and the threshold power level 225 of each LE-FSL section 100, 110, 120 (and/or coil) required to achieve the target threshold power level and dynamic range can be calculated iteratively. An effective radius of the coiled portion of conductive material 65 required to attain the threshold power level 225 and limiting dynamic range 335 for each LE-FSL section 100, 110, 120 in the multi-element cascaded LE-FSL device 10 can be calculated (step 350) iteratively. A cascaded LE-FSL device 10 can be fabricated, tested and evaluated (e.g. step 220). Measured performance values for the fabricated cascaded LE-FSL device 10 can be compared with performance values calculated using specific design parameters. In this manner, a set of design parameters that render specific performance values for specific operating parameters can be determined, iteratively if needed, and these target operating performance parameters can be compared with results from a fabricated cascade LE-FSL device, wherein the fabricated LE-FSL device can be designed to be impedance matched for a transmission line (step 400).

According to aspects of the present invention, the desired operating parameters for at least one LE-FSL section 100 can be attained by modifications of coil radius (corresponding to a dimension, s, bounding the ferrite-based material 30), the width of the portion of conductive material 65, the number of the at least one LE-FSL section 100, and/or an impedance of the equivalent circuit 180 by modifying at least one capacitance of at least one capacitor in the operational circuit.

In practice, a design method, such as but not limited to the one described above, can be used to optimize the design parameters for an LE-FSL device 10 (comprising, e.g., a single lumped element, a plurality of lumped elements in a plurality of configurations, including a cascaded configuration, and combinations thereof). Both design and fabrication process steps can be defined prior to experimentation in the lab and device fabrication. In operation, novel LE-FSL device structures 10, such as those described herein, can be fabricated according to design parameters selected for specific operating performance requirements in well-defined LE-FSL embedded systems.

With methods relating to efficient LE-FSL design and fabrication, ferrite-based material 30, fabrication of LE-FSL device 10 structures, and systems embedded with performance-tailored LE-FSL device designs, low cost differential signal attenuating devices that can operate over a larger parameter space and with higher performance than has heretofore been possible can be attained. As examples, the methods, compositions, and apparatus described herein can enable lower threshold power level 225 operation, reduced insertion loss, narrowed absorption bandwidth, increased dynamic range and high frequency operation of differential signal attenuating devices at relatively low cost, while accommodating increasing restrictions on device size. Applications of these methods, compositions, and apparatus are numerous, and include a wide range of devices used in wireless communications, radar and other defense electronic systems.

Numerous modifications and alternative embodiments of the present invention will be apparent to those skilled in the art in view of the foregoing description. Accordingly, this description is to be construed as illustrative only and is for the purpose of teaching those skilled in the art the best mode for carrying out the present invention. Details of the structure may vary substantially without departing from the spirit of the present invention, and exclusive use of all modifications that come within the scope of the appended claims is reserved. Within this specification embodiments have been described in a way which enables a clear and concise specification to be written, but it is intended and will be appreciated that embodiments may be variously combined or separated without parting from the invention. It is intended that the present invention be limited only to the extent required by the appended claims and the applicable rules of law.

It is also to be understood that the following claims are to cover all generic and specific features of the invention described herein, and all statements of the scope of the invention which, as a matter of language, might be said to fall there-between.

What is claimed is:

1. A device, comprising:
a first lumped element inductor comprising a ferrite-based material;
wherein, above a selected threshold power level, a signal passing through the first lumped element inductor is attenuated with frequency selectivity at select frequencies.

2. The device of claim 1, wherein an electrical length of the first lumped element inductor is less than or equal to approximately 0.1 times a wavelength of the signal, the signal comprising a frequency at and above approximately 1 GHz.

3. The device of claim 1, further comprising a second lumped element inductor.

4. The device of claim 3, wherein the second lumped element inductor is arranged relative to the first lumped element inductor in a cascaded configuration.

5. The device of claim 4, wherein the second lumped element inductor is arranged relative to the first lumped element inductor in a cascaded configuration according to threshold power level.

6. The device of claim 1, wherein the device further comprises an additional lumped element and wherein the additional lumped element is an inductor or a capacitor.

7. The device of claim 6, wherein the additional lumped element comprises at least one of a plurality of planar inductors, at least one of a plurality of thin film capacitors, or a combination thereof.

8. The device of claim 1, wherein the device exhibits frequency selective power attenuation at frequencies at and above approximately 1 GHz.

9. The device of claim 1, wherein the device is operable in the absence of frequency-dependent tuning of the device and frequency-dependent selection of the device.

10. The device of claim 1, wherein the device is integrated into a transmission line structure.

11. The device of claim 10, wherein a characteristic impedance of a transmission line is decreased to approximately match an equivalent resistance representing power absorbed in the ferrite-based material.

12. The device of claim 1, wherein the device is configured for integration into an apparatus.

13. The device of claim 1, wherein upon receipt of the signal, a current flowing through a conductive portion of the first lumped element inductor generates an RF magnetic field that couples to a spin system in the ferrite-based material, causing frequency selective power attenuation.

14. The device of claim 1, wherein the signal below the selected threshold power level is separated from the signal above the selected threshold power level by a quantity larger than a product of a gyromagnetic ratio and a spin-wave linewidth of a material through which the signal passes.

15. The device of claim 1, wherein the device operates over a bandwidth of at least an octave.

16. The device of claim 1, wherein the ferrite-based material comprises a polycrystalline microstructure or a single crystal microstructure.

17. The device of claim 1, wherein the ferrite-based material comprises an FMR linewidth no more than 20 times wider than that of a single crystal YIG film.

18. The device of claim 1, wherein the threshold power level is less dependent on s a spin wave linewidth of the ferrite-based material than is a device that is not structured as a lumped element inductor.

19. The device of claim 1, wherein the device comprises an area of less than approximately 100 mm² while exhibiting a limiting dynamic range of at least approximately 20 dB.

20. The device of claim 1, wherein a first surface of a first material and a second surface of a second material are configured and arranged such that the first surface and the second surface are in intimate contact with each other; and wherein the first surface is a surface layer of the ferrite-based material and the second surface is a surface layer of the first lumped element inductor.

21. The device of claim 1, wherein the selected threshold power level is a minimum near a center frequency of the device.

22. A device comprising:
a portion of conductive material; and
a portion of ferrite-based material;
wherein the portion of ferrite-based material is arranged proximal to the portion of conductive material, thereby, above a threshold power level, attenuating, at select frequencies, a signal passing there-though with frequency selectivity; and
wherein an electrical length of the device is substantially less than a wavelength of the signal.

23. The device of claim 22, wherein a surface of the portion of conductive material and a surface of a ferrite-based material are configured using a thin film deposition technique.

24. The device of claim 22, wherein the portion of conductive material can be configured and arranged in the form of a solenoid coil, a toroid, a non-planar spiral, a planar spiral, and combinations thereof.

25. The device of claim 22, wherein the device exhibits frequency selective power attenuation at frequencies at and above approximately 1 GHz.

26. The device of claim 22, wherein the portion of ferrite-based material comprises an FMR linewidth no more than 20 times wider than that of a single crystal YIG film.

27. The device of claim 22, wherein the threshold power level is less dependent on a spin wave linewidth of the ferrite-based material than a device that is not structured as a lumped element inductor.

28. The device of claim 22, wherein a first surface of a first material and a second surface of a second material are configured and arranged such that the first surface and the second surface are in intimate contact with each other; and wherein the first surface is a surface layer of the volume of ferrite-based material and the second surface is a surface layer of the portion of conductive material.

29. The device of claim 22, wherein when an RF magnetic field penetrating the portion of ferrite-based material bounded by the portion of conductive material reaches a critical magnetic field, the portion of ferrite-based material exhibits frequency selective power attenuation.

30. The device of claim 22, wherein a current flowing through the portion of conductive material generates an RF magnetic field that couples to a spin system in the portion of ferrite-based material.

31. The device of claim 22, wherein a length of the portion of conductive material is substantially less than the wavelength of a signal passing through the device.

32. A method of manufacturing a device comprising:
configuring a portion of conductive material and a portion of ferrite-based material in relation to each other; and
wherein, upon receiving a signal comprising a frequency at and above approximately 1 GHZ, a signal passing through the device is attenuated with frequency selectivity.

33. The method of claim 32, wherein configuring comprises at least one technique that can be selected from a group consisting of powder compaction, sintering, tape-casting and low temperature co-fired ceramic processing, and microelectronic processing methods such as thin film deposition, lithography and etching.

34. A method for designing a device comprising:
providing a mathematical model and using the mathematical model, thereby providing a frequency selective limiting device comprising a performance characteristic with approximately a pre-selected value;
incorporating a lumped element inductor comprising a ferrite-based material into the mathematical model; and
selecting an electrical length of the lumped element inductor to be substantially less than a wavelength of a signal passing through the lumped element inductor.
